(19) United States
(12) Patent Application Publication
(10) Pub. No.: US 2024/0004290 A1
(43) Pub. Date: Jan. 4, 2024

(54) RESIN COMPOSITION, CURED FILM AND COLOR FILTER

(71) Applicant: Advanced Echem Materials Company Limited, Taoyuan (TW)

(72) Inventors: Jui-Yu Hsu, Taoyuan (TW); Yu-Lun Li, Taoyuan (TW)

(73) Assignee: Advanced Echem Materials Company Limited, Taoyuan (TW)

(21) Appl. No.: 18/344,883

(22) Filed: Jun. 30, 2023

(30) Foreign Application Priority Data
Jun. 30, 2022 (TW) 111124416

(51) Int. Cl. G03F 7/033; G03F 7/00; G03F 7/031

(52) U.S. Cl. CPC G03F 7/033; G03F 7/0007; G03F 7/031

(57) ABSTRACT

A resin composition, a cured film and a color filter are provided. The resin composition includes a resin (A), a polymerizable monomer (B), a photopolymerization initiator (C), a photoacid generator (D), a black colorant (E) and a solvent (F). The resin (A) includes an alkali-soluble resin (A-1) and a styrene-based resin (A-2). A weight average molecular weight of the alkali-soluble resin (A-1) is 2,000 to 20,000. The alkali-soluble resin (A-1) includes a structural unit having a fluorene ring and two or more ethylenic polymerizable groups. The polymerizable monomer (B) includes a polyurethane acrylate oligomer (B-1).

### CROSS-REFERENCE TO RELATED APPLICATION

This application claims the priority benefit of Taiwan application serial no. 111124416, filed on Jun. 30, 2022. The entirety of the above-mentioned patent application is hereby incorporated by reference herein and made a part of this specification.

### BACKGROUND

### Technical Field

The invention relates to a resin composition, particularly to a resin composition, a cured film, and a color filter.

### Description of Related Art

The outer frame of the panel of the display device is provided with a light-shielding film to block light leakage around the panel, so as to suppress the phenomenon of light leakage when the screen is displayed in black, and to suppress the phenomenon of color mixing between adjacent color filter patterns. At present, the light-shielding property of the light-shielding film is often improved by increasing the concentration of the black pigment in the light-shielding film. However, increasing the concentration of the black pigment in the light-shielding film may cause phenomena such as blurring of mask patterns, development residues, and poor reactivity during the development process, thereby affecting the performance of the device using the same.

### SUMMARY

The invention provides a resin composition, a cured film, and a color filter capable of providing good resolution, light-shielding property, adhesion and which are less prone to undercutting.

A resin composition of the invention includes a resin (A), a polymerizable monomer (B), a photopolymerization initiator (C), a photoacid generator (D), a black colorant (E) and a solvent (F). The resin (A) includes an alkali-soluble resin (A-1) and a styrene-based resin (A-2). A weight average molecular weight of the alkali-soluble resin (A-1) is 2,000 to 20,000. The alkali-soluble resin (A-1) includes a structural unit having a fluorene ring and two or more ethylenic polymerizable groups. The polymerizable monomer (B) includes a polyurethane acrylate oligomer (B-1).

In an embodiment of the invention, the structural unit having a fluorene ring and two or more ethylenic polymerizable groups includes a structural unit represented by Formula (A1) as follows:

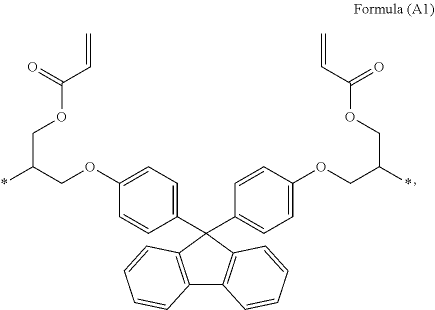

in Formula (A1), * represents a bonding position.

In an embodiment of the invention, the styrene-based resin (A-2) includes a structural unit represented by Formula (A2) as follows:

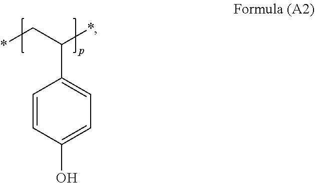

in Formula (A2), p represents an integer from 20 to 50, and * represents a bonding position.

In an embodiment of the invention, the polyurethane acrylate oligomer (B-1) includes a structural unit represented by Formula (B1) as follows or a structural unit derived from a compound represented by Formula (B2) as follows:

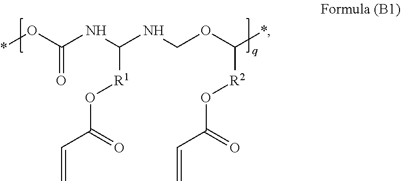

in Formula (B1), R¹ and R² each represent a divalent organic group, q represents an integer from 5 to 20, and * represents a bonding position;

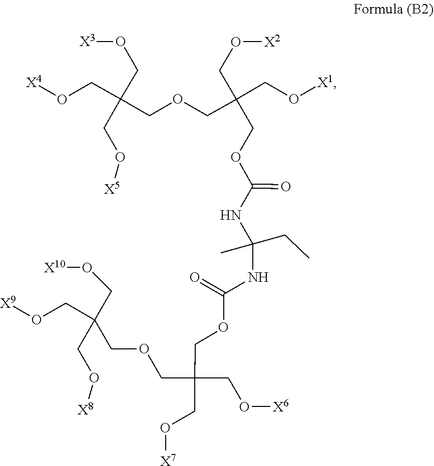

in Formula (B2), X¹ to X¹⁰ each represent a hydrogen atom, an acryl group or a methylacryl group, wherein at least two of X¹ to X¹⁰ are an acryl group or a methylacryl group.

In an embodiment of the invention, the polymerizable monomer (B) further includes a triazine-based monomer (B-2).

In an embodiment of the invention, the polymerizable monomer (B) further includes a triazine-based monomer (B-2) represented by Formula (B3) as follows:

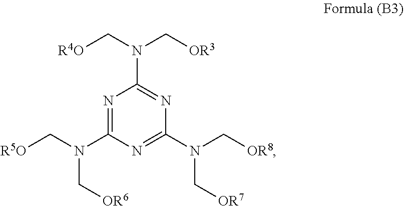

in Formula (B3), R³ to R⁸ each represent an alkyl group having 1 to 6 carbon atoms.

In an embodiment of the invention, the photopolymerization initiator (C) includes an oxime ester-based compound.

In an embodiment of the invention, the photoacid generator (D) includes a propanesulfonic acid-based compound.

In an embodiment of the invention, the black colorant (E) includes a carbon black (E-1), a titanium black (E-2), or a combination thereof.

In an embodiment of the invention, based on a usage amount of 100 parts by weight of the resin composition, a usage amount of the carbon black (E-1) is 10 parts by weight to 40 parts by weight, and a usage amount of the titanium black (E-2) is 30 parts by weight to 70 parts by weight.

In an embodiment of the invention, the solvent (F) includes propylene glycol monomethyl ether, propylene glycol monomethyl ether acetate, dipropylene glycol monomethyl ether acetate, propylene glycol monoethyl ether, propylene glycol monopropyl ether, or a combination thereof.

In an embodiment of the invention, the resin composition further includes a surfactant (G). The surfactant (G) includes a fluorine-based surfactant, a siloxane-based surfactant, a nonionic surfactant, or a combination thereof.

In an embodiment of the invention, based on a usage amount of 100 parts by weight of the resin composition, a usage amount of the resin (A) is 6 parts by weight to 40 parts by weight, a usage amount of the polymerizable monomer (B) is 2 parts by weight to 40 parts by weight, a usage amount of the photopolymerization initiator (C) is 0.01 parts by weight to 10 parts by weight, a usage amount of the photoacid generator (D) is 0.01 parts by weight to 10 parts by weight, a usage amount of the black colorant (E) is 40 parts by weight to 88 parts by weight, and a usage amount of the solvent (F) is 0.1 parts by weight to 20 parts by weight.

A cured film of the invention is formed by curing the resin composition described above.

A color filter of the invention includes a black matrix. The black matrix is formed by curing the resin composition described above.

Based on the above, as the resin composition of the invention includes a resin (A) and a polymerizable monomer (B), the resin (A) includes an alkali-soluble resin (A-1) and a styrene-based resin (A-2), the alkali-soluble resin (A-1) includes a structural unit having specific structure, and the polymerizable monomer (B) includes a polyurethane acrylate oligomer (B-1). Thus, when the resin composition is used to form a cured film, the cured film may have good resolution, light-shielding property, adhesion and which are less prone to undercutting and thereby suitable for the black matrix and the color filter including the same.

To make the features and advantages of the disclosure to be comprehended more easily, embodiments and drawings are described in detail as follows.

### BRIEF DESCRIPTION OF THE DRAWINGS

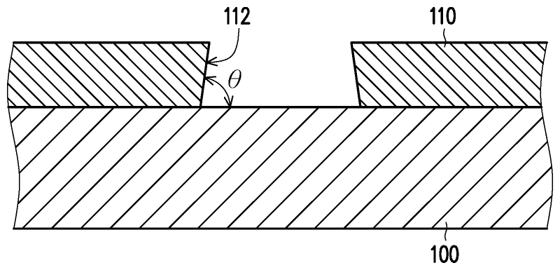

The FIG. 1s a schematic diagram of the present invention for evaluating the degree of undercutting.

### DESCRIPTION OF THE EMBODIMENTS

### <Resin Composition>

The invention provides a resin composition including a resin (A), a polymerizable monomer (B), a photopolymerization initiator (C), a photoacid generator (D), a black colorant (E) and a solvent (F). In addition, the resin composition of the invention may further include a surfactant (G) as needed. The components are described hereinafter in detail.

It is explained here that the “tetravalent organic group” as used in the specification is an organic group having four bonding positions. And the “tetravalent organic group” may form four chemical bonds through these four bonding positions.

The “divalent organic group” as used in the specification is an organic group having two bonding positions. And the “divalent organic group” may form two chemical bonds through these two bonding positions.

### Resin (A)

The resin (A) includes an alkali-soluble resin (A-1) and a styrene-based resin (A-2). The resin (A) may further include other suitable resins.

A weight average molecular weight of the alkali-soluble resin (A-1) is 2,000 to 20,000, preferably 4,000 to 10,000. The alkali-soluble resin (A-1) includes a structural unit having a fluorene ring and two or more ethylenic polymerizable groups. In this embodiment, the structural unit having a fluorene ring and two or more ethylenic polymerizable groups may include a structural unit represented by Formula (A1) as follows:

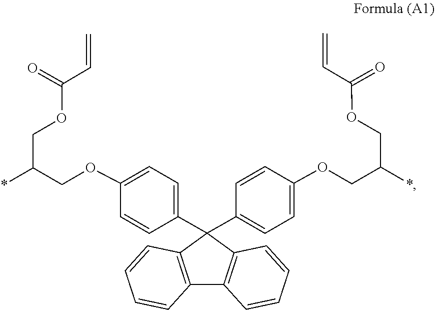

in Formula (A1), * represents a bonding position.

Moreover, the structural unit represented by Formula (A1) is derived from a monomer represented by Formula (A1-1) as follows.

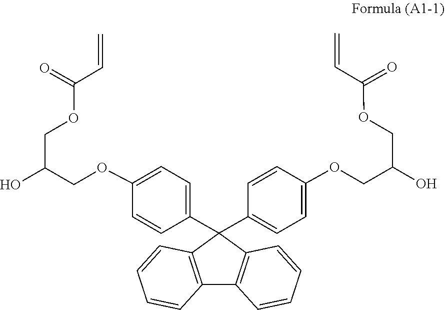

The alkali-soluble resin (A-1) may be a cardo resin formed by polymerizing a monomer having a fluorene ring and two or more ethylenically-polymerizable groups, tetracarboxylic dianhydride, and dicarboxylic acid, wherein the monomer having a fluorene ring and two or more ethylenically-polymerizable groups is preferable the monomer represented by Formula (A1-1) above. Tetracarboxylic dianhydride and dicarboxylic acid are not particularly limited, and suitable tetracarboxylic dianhydride and dicarboxylic acid may be selected as needed. For example, the compound forming a structural unit having a fluorene ring and two or more ethylenically-polymerizable groups may include a bisphenol fluorene-based compound having two or more ethylenically-polymerizable groups obtained by reacting a bisphenol fluorene-based compound with an ethylenically unsaturated group compound. The bisphenol fluorene-based compound may include 9,9-bis(4-hydroxyphenyl) fluorene, 9,9-bis(4-hydroxy-3-methylphenyl) fluorene, 9,9-bis(4-amino-3-chlorophenyl) fluorene, 9,9-bis(4-bromophenyl)-9H-fluorene, 9,9-bis(4-amino-3-fluorophenyl) fluorene or other suitable bisphenol fluorene-based compounds. The method of synthesizing the alkali-soluble resin (A-1) is not particularly limited, and a monomer having a fluorene ring and two or more ethylenically-polymerizable groups, tetracarboxylic dianhydride, and dicarboxylic acid may be polymerized into a structural unit having a fluorene ring and two or more ethylenically-polymerizable groups using a conventional organic synthesis method.

Specific examples of the alkali-soluble resin (A-1) include a cardo resin (trade name CX-01, manufactured by TAKOMA Ltd.).

Based on the usage amount of 100 parts by weight of the resin composition, a usage amount of the alkali-soluble resin (A-1) is 5 parts by weight to 20 parts by weight, preferably 7 parts by weight to 9 parts by weight.

When the alkali-soluble resin (A-1) is included in the resin composition, the cured film formed by the resin composition are able to provide better adhesion.

The styrene-based resin (A-2) is not particularly limited, and any suitable styrene-based resin may be selected according to needs. For example, the styrene-based resin (A-2) may include styrene resin or other suitable styrene-based resin. The styrene-based resin (A-2) may be used alone or in combination. In this embodiment, the styrene-based resin (A-2) may include a structural unit represented by Formula (A2) as follows:

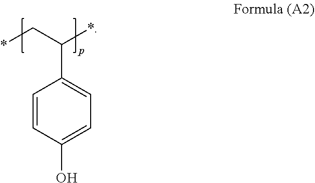

In Formula (A2), p represents an integer from 20 to 50, preferably an integer from 25 to 45; and * represents a bonding position.

Based on the usage amount of 100 parts by weight of the resin composition, a usage amount of the styrene-based resin (A-2) is 1 part by weight to 20 parts by weight, preferably 2 parts by weight to 3 parts by weight.

Based on the usage amount of 100 parts by weight of the resin composition, a usage amount of the resin (A) is 6 parts by weight to 40 parts by weight, preferably 10 parts by weight to 11 parts by weight.

### Polymerizable Monomer (B)

The polymerizable monomer (B) includes a polyurethane acrylate oligomer (B-1). In this embodiment, the polymerizable monomer (B) may further include a triazine-based monomer (B-2) or other suitable polymerizable monomers.

The polyurethane acrylate oligomer (B-1) is not particularly limited, and any suitable polyurethane acrylate oligomer may be selected according to needs. For example, the polyurethane acrylate oligomer (B-1) may include a polyurethane acrylate oligomer (trade name DPHA-40H, manufactured by Nippon Kayaku Co., Ltd.), or other suitable polyurethane acrylate oligomers. The polyurethane acrylate oligomer (B-1) may include one structural unit or a combination of two or more structural units. In this embodiment, the polyurethane acrylate oligomer (B-1) includes a structural unit represented by Formula (B1) as follows or a structural unit derived from a compound represented by Formula (B2) as follows.

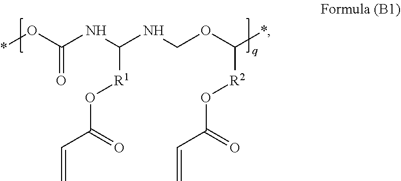

in Formula (B1), R¹ and R² each represent a divalent organic group, q represents an integer from 5 to 20, and * represents a bonding position.

In Formula (B1), R¹ and R² preferably represent an alkylene group having 4 to 12 carbon atoms or an alkoxylene group having 4 to 12 carbon atoms, more preferably an alkoxylene group having 4 to 7 carbon atoms; and q preferably represents an integer from 7 to 15.

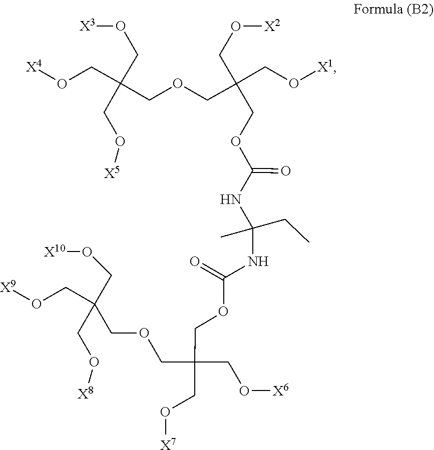

in Formula (B32), X¹ to X¹⁰ each represent a hydrogen atom, an acryl group or a methylacryl group, wherein at least two of X¹ to X¹⁰ are an acryl group or a methylacryl group.

In Formula (B32), X¹ to X¹⁰ each preferably represent an acryl group.

Based a usage amount of 100 parts by weight of the resin composition, a usage amount of the polyurethane acrylate oligomer (B-1) is 1 part by weight to 20 parts by weight, preferably 2 parts by weight to 4 parts by weight.

The triazine-based monomer (B-2) is not particularly limited, and any suitable triazine-based monomer may be selected according to needs. In this embodiment, the triazine-based monomer (B-2) may include a melamine-based monomer (e.g. CYMEL (trade name, manufactured by Allnex GMBH)) or other suitable triazine-based monomers. The triazine-based monomer (B-2) may be used alone or in combination.

In this embodiment, the triazine-based monomer (B-2) may include a compound represented by Formula (B3) as follows:

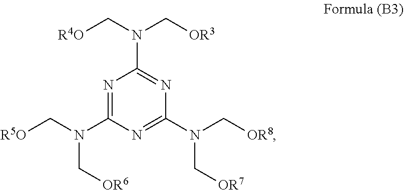

In Formula (B3), R³ to R¹ each represent an alkyl group having 1 to 6 carbon atoms, preferably an alkyl group having 1 to 3 carbon atoms.

Based on a usage amount of 100 parts by weight of the resin composition, a usage amount of the triazine-based monomer (B-2) is 1 part by weight to 20 parts by weight, preferably 1 part by weight to 3 parts by weight.

Based on a usage amount of 100 parts by weight of the resin composition, a usage amount of the polymerizable monomer (B) is 2 parts by weight to 40 parts by weight, preferably 4 parts by weight to 5 parts by weight.

### Photopolymerization Initiator (C)

The photopolymerization initiator (C) is not particularly limited, and any suitable photopolymerization initiator may be selected according to needs. In this embodiment, the photopolymerization initiator (C) may include an oxime ester-based compound or other suitable photopolymerization initiators. The oxime ester-based compound may include Irgacure OXE-03 (trade name, manufactured by BASF) or other suitable oxime-ester based compounds. The photopolymerization initiator (C) may be used alone or in combination. In this embodiment, the photopolymerization initiator (C) is preferably Irgacure OXE-03.

Based on a usage amount of 100 parts by weight of the resin composition, a usage amount of the photopolymerization initiator (C) is 0.01 parts by weight to 10 parts by weight, preferably 0.5 parts by weight to 1.5 parts by weight, more preferably 0.7 parts by weight to 1.1 parts by weight.

### Photoacid Generator (D)

The photoacid generator (D) is not particularly limited, and any suitable photoacid generator may be selected according to needs. In this embodiment, the photoacid generator (D) may include a propanesulfonic acid-based compound or other suitable photoacid generators. The propanesulfonic acid-based compound may include Irgacure PAG 103 (trade name, manufactured by BASF) or other suitable propanesulfonic acid-based compounds. The photoacid generator (D) may be used alone or in combination.

Based on a usage amount of 100 parts by weight of the resin composition, a usage amount of the photoacid generator (D) is 0.01 parts by weight to 10 parts by weight, preferably 0.05 parts by weight to 0.15 parts by weight, more preferably 0.09 parts by weight to 0.13 parts by weight.

Based on a usage amount of 100 parts by weight of the alkali-soluble resin (A-1), a sum of the usage amount of the photopolymerization initiator (C) and the usage amount of the photoacid generator (D) is 1 part by weight to 50 parts by weight, preferably 10 parts by weight to 15 parts by weight.

### Black Colorant (E)

The black colorant (E) is not particularly limited, and any suitable black colorant may be selected according to needs. In this embodiment, the black colorant (E) may include a carbon black (E-1), a titanium black (E-2), or a combination thereof. The black colorant (E) may be used alone or in combination. In this embodiment, the black colorant (E) is preferably a combination of the carbon black (E-1) and the titanium black (E-2).

Based on a usage amount of 100 parts by weight of the resin composition, a usage amount of the black colorant (E) is 40 parts by weight to 88 parts by weight, preferably 83 parts by weight to 84 parts by weight.

Based on a usage amount of 100 parts by weight of the resin composition, a usage amount of the carbon black (E-1) is 10 parts by weight to 40 parts by weight, preferably 22 parts by weight to 34 parts by weight; and a usage amount of the titanium black (E-2) is 30 parts by weight to 70 parts by weight, preferably 58 parts by weight to 59 parts by weight.

### Solvent (F)

The solvent (F) is not particularly limited, and any suitable solvent may be selected according to needs. For example, the solvent (F) may include a glycol ether-based compound, an acetate-based compound or other suitable solvents. The glycol ether-based compound may include cellosolve, methyl cellosolve, ethyl cellosolve, carbitol, methyl carbitol, ethyl carbitol, butyl carbitol, propylene glycol monomethyl ether, propylene glycol monoethyl ether, propylene glycol monopropyl ether, dipropylene glycol monomethyl ether, dipropylene glycol monoethyl ether, triethylene glycol monomethyl ether, triethylene glycol monoethyl ether or other suitable glycol ether-based compounds. The acetate-based compound may include ethyl acetate, butyl acetate, cellosolve acetate, ethyl cellosolve acetate, butyl cellosolve acetate, carbitol acetate, ethyl carbitol acetate, butyl carbitol acetate, propylene glycol monomethyl ether acetate (PGMEA), dipropylene glycol monomethyl ether acetate or other suitable acetate-based compounds. The solvent (F) may be used alone or in combination. In this embodiment, the solvent (F) is preferably propylene glycol monomethyl ether, propylene glycol monomethyl ether acetate, dipropylene glycol monomethyl ether acetate, propylene glycol monoethyl ether, propylene glycol monopropyl ether, or a combination thereof, more preferably propylene glycol monomethyl ether acetate.

Based on a usage amount of 100 parts by weight of the resin composition, a usage amount of the solvent (F) is 0.1 parts by weight to 20 parts by weight, preferably 0.5 parts by weight to 1.5 parts by weight, more preferably 0.6 parts by weight to 1.1 parts by weight.

When the resin composition includes the solvent (F), the resin composition is able to have appropriate viscosity, which provides good coating uniformity to form a cured film having good surface flatness.

### Surfactant (G)

The surfactant (G) is not particularly limited, and any suitable surfactant may be selected according to needs. For example, the surfactant (G) may include a fluorine-based surfactant, a siloxane-based surfactant, a nonionic surfactant, or other suitable surfactants. The surfactant (G) may be used alone or in combination.

Based on a usage amount of 100 parts by weight of the resin composition, a usage amount of the surfactant (G) is 0.01 parts by weight to 10 parts by weight, preferably 0.05 parts by weight to 0.15 parts by weight.

### <Preparation of Resin Composition>

The preparation of the resin composition is not particularly limited. For example, the resin (A), the polymerizable monomer (B), the photopolymerization initiator (C), the photoacid generator (D), the black colorant (E) and the solvent (F) are stirred in a mixer to be mixed uniformly into a solution state, and a surfactant (G) may also be added if necessary. After mixing them uniformly, a liquid resin composition is obtained.

### <Manufacturing Process of Cured Film>

An exemplary embodiment of the invention provides a cured film formed using the resin composition.

The cured film may be formed by coating the resin composition above on a substrate to form a coating film and performing pre-bake, exposure, development, and post-bake on the coating film. For example, after the resin composition is coated on the substrate to form a coating film, pre-bake is performed at a temperature of 90° C. for 2 minutes. Next, the pre-baked coating film is exposed with an i-line exposure machine at 400 to 1200 J/m². Then, the exposed coating film is developed for 24 seconds. Then, the developed coating film was washed with distilled water and nitrogen gas was blown to dry the coating film. Next, post-bake is performed at 220° C. for 20 minutes to form a cured film with a thickness of 1.5 μm on the substrate.

The substrate may be a glass substrate, a plastic base material (for example, a polyether sulfone (PES) board, a polycarbonate (PC) board, or a polyimide (PI) film), or other light-transmitting substrates, and the type thereof is not particularly limited.

The coating method is not particularly limited, but a spray coating method, a roll coating method, a spin coating method, or the like may be used, and in general, a spin coating method is widely used. In addition, a coating film is formed, and then, in some cases, residual solvent may be partially removed under reduced pressure.

The developing solution is not particularly limited, and a suitable developing solution may be selected as needed. For example, the developing solution may be tetramethyl ammonium hydroxide (TMAH), and the concentration thereof may be 0.3 wt %.

In this embodiment, the cured film with a thickness of 1.0 μm to 1.5 μm has a transmittance of less than 0.4% at a wavelength of 300 nm to 1100 nm.

### <Color Filter>

An exemplary embodiment of the invention provides a color filter including a black matrix. The black matrix is formed by curing the resin composition above. The color filter may further include a filter pattern. The filter pattern may include a red filter pattern, a green filter pattern and a blue filter pattern. The black matrix may be arranged between each filter pattern.

An exemplary embodiment of the invention provides the cured film or the color filter having a specific transmittance in the visible light region, and may be applied to devices such as CMOS image sensor (CIS), solid-state photographic element, integrated circuit (IC) semiconductor, light-emitting diode, liquid crystal display, etc.

The invention is described hereinafter in detail with reference to some examples. The following examples are provided to describe the invention, and the scope of the invention includes the categories described in the following claims, their equivalents, and their modifications. The invention is not limited to the scope of those examples.

### Examples of Resin Composition and Cured Film

Example 1 to Example 4 and Comparative example 1 to Comparative example 4 of the resin composition and the cured film are described below:

### Example 1

a. Resin Composition

7.846 parts by weight of cardo resin (trade name CX-01, manufactured by TAKOMA Ltd.), 2.234 parts by weight of styrene-based resin (A-2) including the structural unit represented by Formula (A2), 2.670 parts by weight of DPHA-40H (trade name, manufactured by Nippon Kayaku Co., Ltd.), 2.320 parts by weight of the triazine-based monomer (B-2) represented by Formula (B3), 1.032 parts by weight of the oxime ester-based compound represented by Formula (C1), 0.124 parts by weight of the propanesulfonic acid-based compound represented by Formula (D1), 25 parts by weight of the carbon black and 58.14 parts by weight of the titanium black were added in 0.634 parts by weight of propylene glycol monomethyl ether acetate (PGMEA). After stirring uniformly with a stirrer, the resin composition of Example 1 was obtained.

b. Cured Film

Each resin composition prepared in the examples was coated on a substrate by a spin coating method (spin coater model: MK-VIII, manufactured by Tokyo Electron Limited (TEL), rotation speed: about 600 rpm). Then, pre-bake was performed at a temperature of 90° C. for 2 minutes to form a film. Then, exposure was performed at 400 to 1200 J/m² using an i-line exposure machine (exposure machine model: 5500iZa, manufactured by Cannon) to form a semi-finished product. Next, development was performed at a temperature of 23° C. using TMAH having a concentration of 0.3 wt % as a developing solution for 24 seconds. Then, the developed coating film was washed with distilled water and nitrogen gas was blown to dry the coating film. Next, post-bake was performed at 220° C. for 20 minutes to obtain the cured films with a pattern thickness of 1.5 μm. The obtained cured films were evaluated by each of the following evaluation methods, and the results thereof are as shown in Table 2.

### Example 2 to Example 4 and Comparative Example 1 to Comparative Example 4

The resin compositions of Example 2 to Example 4 and Comparative example 1 to Comparative example 4 were prepared using the same steps as Example 1, and the difference thereof is: the type and the usage amount of the components of the resin compositions were changed (as shown in Table 2), wherein the components/compounds corresponding to the symbols in Table 2 are shown in Table 1. The obtained resin compositions were made into cured films and evaluated by each of the following evaluation methods, and the results thereof are as shown in Table 2.

TABLE 1

| | Symbol | Components/compounds |
|---|---|---|
| Resin (A) | A-1 | Cardo resin (trade name CX-01, manufactured by |
| | | TAKOMA Ltd.) |
| | A-2 | Styrene-based resin (A-2) including the structural unit |
| | | represented by Formula (A2), wherein in Formula (A2), p |
| | | represents an integer from 30 to 35. |
| | A-3 | Resin including structural units represented by Formula (A3) |
| | | to Formula (A5), |
| | | 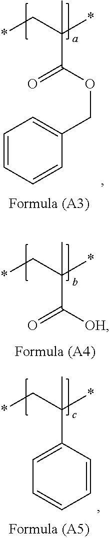 |
| | | in Formula (A3) to Formula (A5), a represents an integer |
| | | from 110 to 130, b represents an integer from 50 to 70, c |
| | | represents an integer from 55 to 75, and * represents a |
| | | bonding position. |
| Polymerizable | B-1 | DPHA-40H (trade name, manufactured by Nippon Kayaku |
| monomer (B) | | Co., Ltd.) |
| | B-2 | Triazine-based monomer (B-2) represented by Formula |
| | | (B3), wherein R³ to R⁸ each represent a methyl group, an |
| | | ethyl group or a n-propyl group. |
| | B-3 | Dipentaerythritol hexaacrylate (DPHA) |
| Photopolymerization | C-1 | Oxime ester-based compound represented by Formula (C1), |
| initiator (C) | | |
| | | 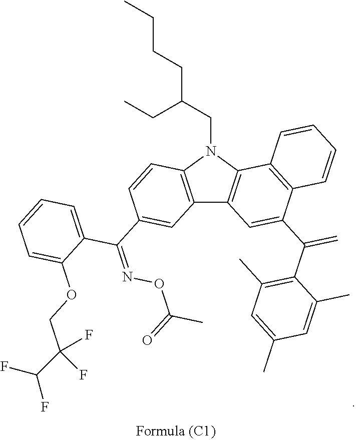 [SMILES: C=C(c1c(C)cc(C)cc1C)c1cc2c3cc(/C(=N\OC(C)=O)c4ccccc4OCC(F)(F)C(F)F)ccc3n(CC(CC)CCCC)c2c2ccccc12] |
| Photoacid generator | D-1 | Propanesulfonic acid-based compound represented by |
| (D) | | Formula (D1), |
| | | 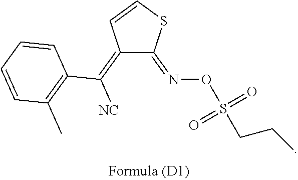 |
| Black colorant (E) | E-1 | Carbon black (manufactured by Nippon Pigment Company |
| | | Limited), and a particle size thereof is less than 100 nm. |
| | E-2 | Titanium black (manufactured by TOKUSHIKI Co., Ltd.), |
| | | and a particle size thereof is less than 100 nm. |
| Solvent (F) | F-1 | Propylene glycol monomethyl ether acetate (PGMEA) |

TABLE 2

| Component | | Examples | | | | Comparative examples | | | |
|---|---|---|---|---|---|---|---|---|---|
| (unit: parts by weight) | | 1 | 2 | 3 | 4 | 1 | 2 | 3 | 4 |
| Resin (A) | A-1 | 7.846 | 7.980 | 8.118 | 7.846 | — | 7.846 | 10.080 | 7.846 |
| | A-2 | 2.234 | 2.272 | 2.312 | 2.234 | 2.234 | 2.234 | — | 2.234 |
| | A-3 | — | — | — | — | 7.846 | — | — | — |
| Polymerizable | B-1 | 2.670 | 3.086 | 3.124 | 3.048 | 3.048 | — | 3.048 | 3.048 |
| monomer (B) | B-2 | 2.320 | 1.572 | 1.590 | 1.554 | 1.554 | 1.554 | 1.554 | 1.554 |
| | B-3 | — | — | — | — | — | 3.048 | — | — |
| Photopolymerization | C-1 | 1.032 | 0.906 | 0.778 | 1.032 | 1.032 | 1.032 | 1.032 | 1.032 |
| initiator (C) | | | | | | | | | |
| Photoacid generator | D-1 | 0.124 | 0.110 | 0.096 | 0.124 | 0.124 | 0.124 | 0.124 | 0.124 |
| (D) | | | | | | | | | |
| Black colorant (E) | E-1 | 25 | 25 | 25 | 25 | 25 | 25 | 25 | — |
| | E-2 | 58.14 | 58.14 | 58.14 | 58.14 | 58.14 | 58.14 | 58.14 | 83.14 |
| Solvent (F) | F-1 | 0.634 | 0.934 | 0.842 | 1.022 | 1.022 | 1.022 | 1.022 | 1.022 |

| | | | | | | | | | |
|---|---|---|---|---|---|---|---|---|---|
| Evaluation | Resolution | ◯ | ◯ | ◯ | ◯ | X | ◯ | ◯ | ◯ |
| results | Light-shielding | ◯ | ◯ | ◯ | ◯ | ◯ | ◯ | ◯ | X |
| | property | | | | | | | | |
| | Adhesion | ◯ | ◯ | ◯ | ◯ | Δ | ◯ | ◯ | Δ |
| | Degree of | ◯ | ◯ | ◯ | ◯ | X | Δ | X | ◯ |
| | undercutting | | | | | | | | |

### <Evaluation Methods>

a. Resolution

The prepared cured film (thickness: 1.5 in) was observed via a Critical Dimension Scanning Electron Microscope (CD-SEM) (Model: S8840, manufactured by Hitachi Co., Ltd.) at a magnification of 12000× to observe integrity of the dot pattern in the area with a critical dimension of 5.0 μm to evaluate the resolution. When the contour of the pattern is more complete, the cured film has good resolution.

The evaluation criteria of resolution are as follows:
O: the contour of the pattern is complete:
Δ: the contour of the pattern is slightly protruding or missing corners, but it does not affect the actual application;
X: the contour of the pattern is not complete.
   b. Light-Shielding Property

The prepared cured film (thickness: 1.5 μm) was measured for transmittance at wavelengths of 300 nm to 1100 nm on the film via a UV-VIS spectrometers (Model: U2900, manufactured by Hitachi Co., Ltd.) to evaluate the light-shielding property. When the transmittance is lower, the cured film has good light-shielding property.

The evaluation criteria of light-shielding property are as follows:
O: transmittance<0.4%;
Δ: 0.4%≤transmittance<1.0%;
X: 1.0%≤transmittance.
   c. Adhesion

The prepared cured film (thickness: 1.5 μm) was observed via an optical microscope (OM) (Model: BH3-SIC6, manufactured by Olympus Corporation) at a magnification of 500× to observe a minimum dimension of the pattern width at which the pattern does not peel off to evaluate the adhesion. When the width for which the pattern does not peel off is smaller, the cured film has good adhesion.

The evaluation criteria of adhesion are as follows:
O: pattern width<10 μm;
Δ: 10 μm≤pattern width<20 μm;
X: 20 μm≤pattern width.
   d. Degree of Undercutting

The prepared cured film (thickness: 1.5 μm) was observed via an scanning electron microscope (SEM) (Model: SU8010, manufactured by Hitachi Co., Ltd) at a magnification of 12000× to observe an angle of the included angle θ between a sidewall 112 of a pattern 110 and a substrate 100 (as shown in the FIGURE) to evaluate the degree of undercutting. When the angle is closer to 90 degrees, the cured film has less undercutting.

The evaluation criteria of degree of undercutting are as follows:
O: 85 degrees≤θ;
Δ: 65 degrees≤θ<85 degrees;
X: θ≤65 degrees.

### <Evaluation Results>

It may be seen from Table 2 that when the resin composition includes the resin (A) and the polymerizable monomer (B), the resin (A) includes the alkali-soluble resin (A-1) and the styrene-based resin (A-2), the alkali soluble resin (A-1) includes the structural unit having specific structure, and the polymerizable monomer (B) includes the polyurethane acrylate oligomer (B-1) (Examples 1 to 4), the cured films formed by the resin composition have good resolution, light-shielding property, adhesion and no obvious undercutting at the same time, and may be suitable for a black matrix and a color filter including the same.

In contrast, when the resin composition does not include the alkali-soluble resin (A-1) including the structural unit having specific structure (Comparative Example 1), the cured film formed by the resin composition has poor resolution and adhesion, and the undercutting occurs; when the resin composition does not include the polyurethane acrylate oligomer (B-1) (Comparative Example 2), the cured film formed by the resin composition has undercutting; when the resin composition does not include the styrene-based resin (A-2) (Comparative Example 3), the cured film formed by the resin composition has undercutting; when the resin composition does not include the carbon black (Comparative Example 4), the cured film formed by the resin composition has poor light-shielding property and adhesion, and may not have good resolution, light-shielding property, adhesion and no obvious undercutting at the same time.

In addition, compared to the cured film (Comparative example 1) formed by the resin composition in which the resin (A) does not include the alkali-soluble resin (A-1) including the structural unit having the specific structure, the cured films (Examples 1 to 4) prepared by the resin composition in which the resin (A) includes the alkali-soluble resin (A-1) including the structural unit having the specific structure have better resolution and adhesion, and do not have obvious undercutting. Therefore, when the resin (A) includes the alkali-soluble resin (A-1) including the structural unit having the specific structure, the cured film formed by the resin composition may have better resolution and adhesion, and do not have obvious undercutting.

In addition, compared to the cured film (Comparative example 2) formed by the resin composition in which the polymerizable monomer (B) does not include the polyurethane acrylate oligomer (B-1), the cured films (Examples 1 to 4) prepared by the resin composition in which the polymerizable monomer (B) includes the polyurethane acrylate oligomer (B-1) do not have obvious undercutting. Therefore, when the polymerizable monomer (B) includes a polyurethane acrylate oligomer (B-1), the cured film formed by the resin composition may not have obvious undercutting.

In addition, compared to the cured film (Comparative example 3) formed by the resin composition in which the resin (A) does not include the styrene-based resin (A-2), the cured films (Examples 1 to 4) prepared by the resin composition in which the resin (A) includes the styrene-based resin (A-2) do not have obvious undercutting. Therefore, when the resin (A) includes the styrene-based resin (A-2), the cured film formed by the resin composition may not have obvious undercutting.

In addition, compared to the cured film (Comparative example 4) formed by the resin composition in which the black colorant (E) does not include the carbon black (E-1), the cured films (Examples 1 to 4) prepared by the resin composition in which the black colorant (E) includes the carbon black (E-1) have better light-shielding property and adhesion. Therefore, when the black colorant (E) includes the carbon black (E-1), the cured film formed by the resin composition may have better light-shielding property and adhesion.

Based on the above, when the resin composition of the invention includes the resin (A) and the polymerizable monomer (B), the resin (A) includes the alkali-soluble resin (A-1) and the styrene-based resin (A-2), the alkali-soluble resin (A-1) includes the structural unit having specific structure, and the polymerizable monomer (B) includes the polyurethane acrylate oligomer (B-1), the cured film formed by the resin composition has good resolution, light-shielding property, adhesion and does not have obvious undercutting at the same time. Therefore, the resin composition may be applied to a black matrix and a color filter including the same, thereby improving the performance of a device using a black matrix and a color filter.

Although the invention has been disclosed in the embodiments above, they are not intended to limit the invention. Anyone with ordinary knowledge in the relevant technical field can make changes and modifications without departing from the spirit and scope of the invention. The scope of protection of the invention shall be subject to those defined by the claims attached.

What is claimed is:

1. A resin composition, comprising:
a resin (A) comprising an alkali-soluble resin (A-1) and a styrene-based resin (A-2), wherein a weight average molecular weight of the alkali-soluble resin (A-1) is 2,000 to 20,000 and the alkali-soluble resin (A-1) comprises a structural unit having a fluorene ring and two or more ethylenic polymerizable groups;
a polymerizable monomer (B) comprising a polyurethane acrylate oligomer (B-1);
a photopolymerization initiator (C);
a photoacid generator (D);
a black colorant (E); and
a solvent (F).

2. The resin composition according to claim 1, wherein the structural unit having a fluorene ring and two or more ethylenic polymerizable groups comprises a structural unit represented by Formula (A1) as follows: 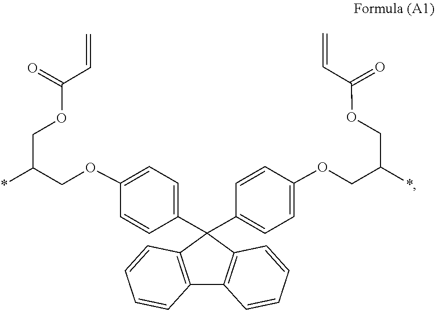
in Formula (A1), * represents a bonding position.

3. The resin composition according to claim 1, wherein the styrene-based resin (A-2) comprises a structural unit represented by Formula (A2) as follows: 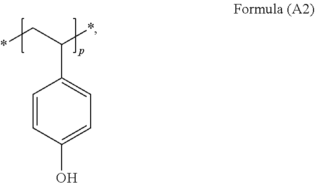
in Formula (A2), p represents an integer from 20 to 50, and * represents a bonding position.

4. The resin composition according to claim 1, wherein the polyurethane acrylate oligomer (B-1) comprises a structural unit represented by Formula (B1) as follows or a structural unit derived from a compound represented by Formula (B2) as follows: 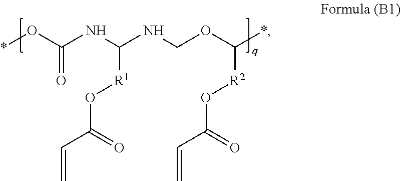
in Formula (B1), R¹ and R² each represent a divalent organic group, q represents an integer from 5 to 20, and * represents a bonding position; 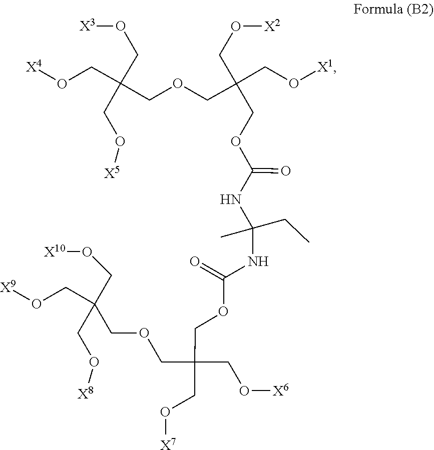
in Formula (B2), X¹ to X¹⁰ each represent a hydrogen atom, an acryl group or a methylacryl group, wherein at least two of X¹ to X¹⁰ are an acryl group or a methylacryl group.

5. The resin composition according to claim 1, wherein the polymerizable monomer (B) further comprises a triazine-based monomer (B-2).

6. The resin composition according to claim 1, wherein the polymerizable monomer (B) further comprises a triazine-based monomer (B-2) represented by Formula (B3) as follows: 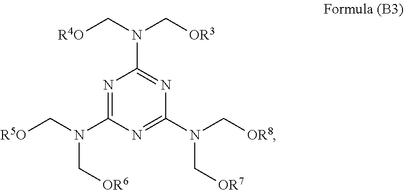
in Formula (B3), R³ to R⁸ each represent an alkyl group having 1 to 6 carbon atoms.

7. The resin composition according to claim 1, wherein the photopolymerization initiator (C) comprises an oxime ester-based compound.

8. The resin composition according to claim 1, wherein the photoacid generator (D) comprises a propanesulfonic acid-based compound.

9. The resin composition according to claim 1, wherein the black colorant (E) comprises a carbon black (E-1), a titanium black (E-2), or a combination thereof.

10. The resin composition according to claim 9, wherein, based on a usage amount of 100 parts by weight of the resin composition, a usage amount of the carbon black (E-1) is 10 parts by weight to 40 parts by weight, and a usage amount of the titanium black (E-2) is 30 parts by weight to 70 parts by weight.

11. The resin composition according to claim 1, wherein the solvent (F) includes propylene glycol monomethyl ether, propylene glycol monomethyl ether acetate, dipropylene glycol monomethyl ether acetate, propylene glycol monoethyl ether, propylene glycol monopropyl ether, or a combination thereof.

12. The resin composition according to claim 1, further comprising a surfactant (G), wherein the surfactant (G) comprises a fluorine-based surfactant, a siloxane-based surfactant, a nonionic surfactant, or a combination thereof.

13. The resin composition according to claim 1, wherein, based on a usage amount of 100 parts by weight of the resin composition, a usage amount of the resin (A) is 6 parts by weight to 40 parts by weight, a usage amount of the polymerizable monomer (B) is 2 parts by weight to 40 parts by weight, a usage amount of the photopolymerization initiator (C) is 0.01 parts by weight to 10 parts by weight, a usage amount of the photoacid generator (D) is 0.01 parts by weight to 10 parts by weight, a usage amount of the black colorant (E) is 40 parts by weight to 88 parts by weight, and a usage amount of the solvent (F) is 0.1 parts by weight to 20 parts by weight.

14. A cured film formed by curing the resin composition according to claim 1.

15. A color filter, comprising: a black matrix formed by curing the resin composition according to claim 1.
